(19) United States
(12) Patent Application Publication
(10) Pub. No.: US 2014/0062523 A1
(43) Pub. Date: Mar. 6, 2014

(54) SEMICONDUCTOR APPARATUS AND TEST METHOD THEREOF

(71) Applicant: SK HYNIX INC., Icheon-si (KR)

(72) Inventors: Chun Seok JEONG, Icheon-si (KR); Kee Teok PARK, Icheon-si (KR)

(73) Assignee: SK HYNIX INC., Icheon-si (KR)

(21) Appl. No.: 13/720,683

(22) Filed: Dec. 19, 2012

(30) Foreign Application Priority Data
Aug. 29, 2012 (KR) 10-2012-0094866

(51) Int. Cl. H01L 23/48; G01R 31/26

(52) U.S. Cl. CPC H01L 23/481; G01R 31/26
USPC 324/762.06; 257/48

(57) ABSTRACT

A semiconductor apparatus includes a chip containing a plurality of through-vias, a test voltage input unit, and a test result reception unit. The test voltage input unit applies a test voltage to one of the plurality of through-vias. The test result reception unit receives an output signal outputted from one or more of the plurality of through-vias.

### CROSS-REFERENCES TO RELATED APPLICATION

The present application claims priority under 35 U.S.C. §119(a) to Korean application number 10-2012-0094866, filed on Aug. 29, 2012, in the Korean Intellectual Property Office, which is incorporated herein by reference in its entirety.

### BACKGROUND

1. Technical Field

The present invention relates generally to a semiconductor apparatus, and more particularly, to a three-dimensional (3D) semiconductor apparatus in which a plurality of chips are stacked, and a test method thereof.

2. Related Art

In order to increase the degree of integration of a semiconductor apparatus, a three-dimensional (3D) semiconductor apparatus configured in such a manner as to increase the degree of integration by stacking and packaging a plurality of chips into a single package has been developed. Recently, a through-silicon via scheme in which silicon vias are formed to pass through the plurality of stacked chips in order to electrically connect the chips together has been used.

The 3D semiconductor apparatus contains a plurality of through-vias such that the plurality of stacked chips can commonly receive various signals. For example, for a memory apparatus, the plurality of stacked chips commonly receives address signals, test signals, input/output line signals, and command signals all through the through-vias.

Various defects may occur in the through-vias, however. For example, the defects may include a void which occurs when a through-via is not completely filled with a conductive material, a bump contact fail which occurs when a chip is bent or a bump material moves, a crack which occurs in a through-via, and so on.

As described above, since the through-vias electrically connect a plurality of chips together, the TSV cannot properly perform the function thereof if a defect occurs, especially if an electrical connection is disconnected due to the defect. Therefore, a test process for accurately detecting a defective through-via, and a repair process for replacing the defective through-via with a normal through-via are required.

FIG. 1 is a diagram illustrating the configuration of a conventional semiconductor apparatus. In FIG. 1, the semiconductor apparatus includes first, second, and third through-vias 11, 12, and 13, respectively, a test voltage application unit 14, a test voltage output unit 15, and a shifting unit 16. The test voltage application unit 14 applies a test voltage VTEST to the first to third through-vias 11 to 13 in response to a test mode signal TM_TSV. The test voltage output unit 15 includes pass gates which are coupled to the first to third through-vias 11 to 13, respectively. The pass gates are turned on in response to section signals SEL<0:2> generated by the shifting unit 16, thereby transmitting current flowing through the first to third through-vias 11 to 13 to a test pad 17. The shifting unit 16 generates the section signals SEL<0:2> from a test mode signal TM.

When a test operation of the semiconductor apparatus is performed, the test voltage application unit 14 applies a test voltage VTEST to the first to third through-vias 11 to 13 concurrently, and the shifting unit 16 enables the selection signals SEL<0:2> in sequential order. As the selection signals SEL<0:2> are enabled in sequential order, current flowing through the first to third through-vias 11 to 13 is transmitted to the test pad 17. It is possible to test whether or not the first to third through-vias 11 to 13 have been properly formed by determining the amount of current measured at test pad 17.

FIG. 2 illustrates the configuration of two semiconductor chips electrically connected by through-vias, and illustrates a defect in the through-vias. When an upper chip 20 and a lower chip 30 are vertically stacked, the through-vias 21 to 23 of the upper chip 20 are electrically connected to the through-vias 31 to 33 of the lower chip 30, respectively, and bumps 25 and 34-36 are used for the electrical connection between the through-vias 21-23 and 31-33. Reference signs “A” and “B” illustrate electrical connections of through-vias which have not been properly formed. Reference sign “A” depicts an open fail, which occurs because a non-existent bump of the upper chip 20 that should be connecting the through-vias 21 and 31 of the upper chip with the lower chip has not been properly formed, and reference sign “B” depicts a short fail, which occurs because a connection between the through-via 22 of the upper chip and an adjacent through-via 33 of the lower chip that should not exist, exists due to the bump 25 of the upper chip being misaligned.

It is possible to detect cases such as “A” as a defect with the configuration of the semiconductor apparatus shown in FIG. 1 with relative ease, but detecting cases such as “B” as a defect with the configuration of the semiconductor apparatus shown in FIG. 1 may be difficult. This is because current flowing through the through-via 22 of the upper chip may be outputted through the through-via 33 of the lower chip, even if the through-via 22 of the upper chip and the through-via 33 of the lower chip are not electrically connected. Therefore, it is required to develop an enhanced semiconductor apparatus capable of detecting all types of defect states on electrical connections between through-vias.

### SUMMARY

A semiconductor apparatus and a test method thereof in which it may optionally select and test a through-via to which a test voltage is applied, contains a through-via which outputs an output signal, and detects defects occurring on the electrical connection of through-vias are described herein.

In an embodiment of the present invention, a semiconductor apparatus which includes a chip containing a plurality of through-vias, includes: a test voltage input unit configured to apply a test voltage to one of the plurality of through-vias, and a test result reception unit configured to receive an output signal outputted from one or more of the plurality of through-vias.

In another embodiment of the present invention, a semiconductor apparatus, which includes an upper chip and a lower chip which are vertically stacked, wherein the upper chip and the lower chip include a respective plurality of through-vias which are mutually electrically connected, includes: an upper-chip test voltage input unit configured to apply a test voltage to a particular through-via among the plurality of through-vias of the upper chip, and a lower-chip test result reception unit, configured to receive output signals outputted from through-vias, which is adjacent to a through-via of the lower chip, and electrically connected to the particular through-via.

In another embodiment of the present invention, a test method of a semiconductor apparatus, in which the semiconductor apparatus includes a first through-via of an upper chip, a second through-via of a lower chip which is electrically connected to the first through-via, and a plurality of adjacent through-vias which are disposed in the vicinity of the second through-via in the lower chip, includes the steps of: outputting a test voltage to the first through-via of the upper chip, and monitoring an output signal outputted through the plurality of adjacent through-vias of the lower chip.

### BRIEF DESCRIPTION OF THE DRAWINGS

Features, aspects, and embodiments are described in conjunction with the attached drawings, in which:

FIG. 1 is a diagram illustrating the configuration of a conventional semiconductor apparatus;

FIG. 2 is a diagram illustrating the conventional configuration of two semiconductor chips electrically connected through through-vias, and illustrates a defect occurring in the connection of the through-vias;

FIG. 3 is a diagram illustrating the configuration of a semiconductor apparatus according to an embodiment of the present invention;

FIG. 4 is a diagram illustrating a configuration capable of being implemented in the upper shifting section shown in FIG. 3; and

FIG. 5 is a diagram illustrating the configuration of a semiconductor apparatus according to another embodiment of the present invention.

### DETAILED DESCRIPTION

Hereinafter, a semiconductor apparatus and a test method thereof according to the present invention will be described below with reference to the accompanying drawings through various embodiments.

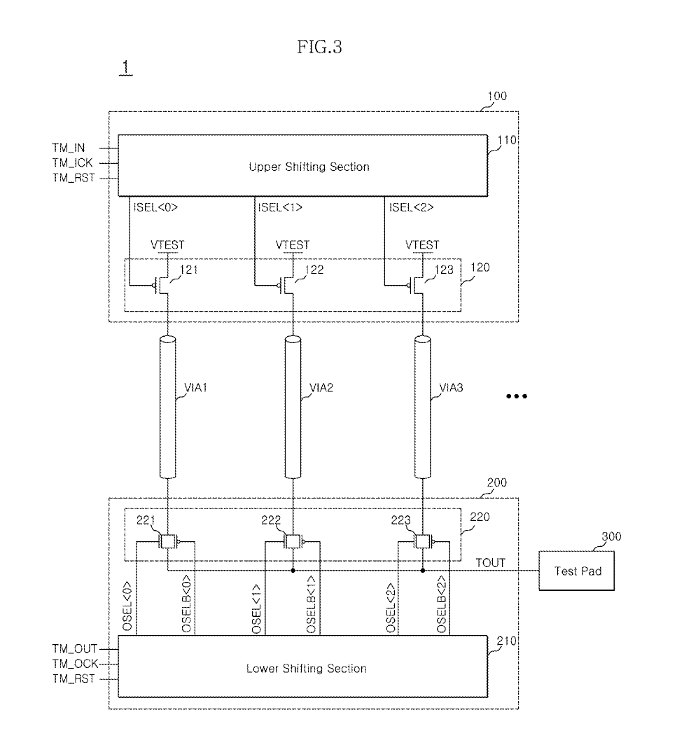

FIG. 3 is a diagram illustrating the configuration of a semiconductor apparatus 1 according to an embodiment of the present invention. In FIG. 3, the semiconductor apparatus 1 includes a first through-via VIA1, a second through-via VIA2, a third through-via VIA3, a test voltage input unit 100, and a test result reception unit 200. The semiconductor apparatus 1 is not limited in the number of through-vias described, but can include a greater number of through-vias. Hereinafter, for a detailed description of the invention, the semiconductor apparatus 1 exhibiting three through-vias VIA1 to VIA3 will be exemplarily described.

The test voltage input unit 100 applies a test voltage VTEST to one or more of the first to third through-vias VIA1 to VIA3. The test voltage input unit 100 may also optionally select a through-via, to which the test voltage VTEST is applied, from among the first to third through-vias VIA1 to VIA3.

The test result reception unit 200 receives an output signal TOUT outputted from one or more of the first to third through-vias VIA1 to VIA3. The test result reception unit 200 may optionally select a through-via, which outputs an output signal TOUT, from among the first to third through-vias VIA1 to VIA3, and may receive the output signal TOUT outputted through the selected through-via. Accordingly, the semiconductor apparatus 1 can freely select a through-via to which a test voltage VTEST is applied, and a through-via which outputs an output signal TOUT. Therefore, it is possible to test the semiconductor apparatus 1 to determine whether or not through-vias have been properly filled with a conductive material and thus properly formed. In addition, it is possible to test the semiconductor apparatus 1 in various manners to determine whether or not the electrical connection of through-vias has been properly formed.

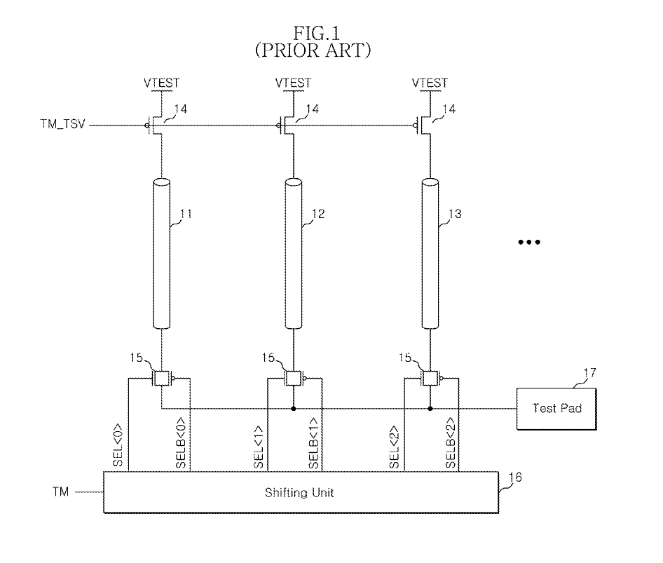

In an embodiment of the present invention, the test voltage input unit 100 can apply a test voltage VTEST to the first through-via VIA1, and the test result reception unit 200 can receive an output signal TOUT outputted through the first through-via VIA1. The testing of the first through-via VIA1 of FIG. 3 is substantially similar to that of FIG. 1. However, a through-via to which the test voltage VTEST is applied and a through-via which outputs the output signal TOUT may be different from each other. For example, the through-via which outputs the output signal TOUT may be a through-via located in the vicinity of the through-via to which the test voltage VTEST is applied. Thus, the semiconductor apparatus 1 according to an embodiment of the present invention can apply the test voltage VTEST to the first through-via VIA1, and receive an output signal TOUT outputted through the second through-via VIA2 that is disposed in the vicinity of the first through-via VIA1.

In FIG. 3, the test voltage input unit 100 includes an upper shifting section 110 and a test voltage application section 120. The upper shifting section 110 generates input selection signals ISEL<0:2> to select one or more of the first to third through-vias VIA1 to VIA3 in response to input control signals TM_IN, TM_ICK, and TM_RST. According to an embodiment of the present invention, the input control signals TM_IN, TM_ICK, and TM_RST can be configured with test mode signals. The input control signals TM_IN, TM_ICK, and TM_RST will be described in more detail later in this specification.

The test voltage application section 120 applies the test voltage VTEST to the first to third through-vias VIA1 to VIA3 in response to the input selection signals ISEL<0:2>. The test voltage application section 120 can include a plurality of transistors which receive the input selection signals ISEL<0:2>, and are then turned on. In FIG. 3, the test voltage application section 120 includes first to third PMOS transistors 121 to 123. The first PMOS transistor 121 has a gate for receiving the input selection signal ISEL<0>, a source for receiving the test voltage VTEST, and a drain connected to one end of the first through-via VIA1. The second PMOS transistor 122 has a gate for receiving the input selection signal ISEL<1>, a source for receiving the test voltage VTEST, and a drain connected to one end of the second through-via VIA2. The third PMOS transistor 123 has a gate for receiving the input selection signal ISEL<2>, a source for receiving the test voltage VTEST, and a drain connected to one end of the third through-via VIA3.

In FIG. 3, the test result reception unit 200 includes a lower shifting section 210 and an output section 220. The lower shifting section 210 generates output selection signals OSEL<0:2> to select one or more of the first to third through-vias VIA1 to VIA3 in response to output control signals TM_OUT, TM_OCK, and TM_RST. According to an embodiment of the present invention, the output control signals TM_OUT, TM_OCK, and TM_RST can be configured with test mode signals. The input control signals TM_IN, TM_ICK, and TM_RST will be described in more detail later in this specification.

The output section 220 provides a test pad 300 with an output signal TOUT outputted through one or more of the first to third through-vias VIA1 to VIA3 in response to the output selection signals OSEL<0:2>. The output section 220 includes a plurality of pass gates which receive the output selection signals OSEL<0:2>, respectively. In FIG. 3, the output section 220 includes first to third pass gates 221 to 223. The first pass gate 221 is turned on in response to the output selection signal OSEL<0> and an inversion signal OSELB<0>, and connects the other end of the first through-via VIA1 to the test pad 300. Accordingly, when the first pass gate 221 is turned on in response to the output selection signal OSEL<0> and the inversion signal OSELB<0>, the first pass gate 221 can provide the test pad 300 with an output signal TOUT outputted through the first through-via VIA1. The second pass gate 222 is turned on in response to the output selection signal OSEL<1> and an inversion signal OSELB<1>, and connects the other end of the first through-via VIA2 to the test pad 300. Accordingly, when the second pass gate 222 is turned on in response to the output selection signal OSEL<1> and the inversion signal OSELB<1>, the second pass gate 222 can provide the test pad 300 with an output signal TOUT outputted through the second through-via VIA2. The third pass gate 223 is turned on in response to the output selection signal OSEL<2> and an inversion signal OSELB<2>, and connects the other end of the third through-via VIA3 to the test pad 300. Accordingly, when the third pass gate 223 is turned on in response to the output selection signal OSEL<2> and the inversion signal OSELB<2>, the third pass gate 223 can provide the test pad 300 with an output signal TOUT outputted through the third through-via VIA3.

The test pad 300 can monitor an output signal TOUT provided from the output section 220 of the test result reception unit 200. The test pad 300 can receive an output signal TOUT provided from the output section 220, and can detect whether or not the electrical connection of the first to third through-vias VIA1 to VIA3 has been properly formed. In an embodiment of the present invention, a detection operation can be performed by measuring the amount of current outputted from the test pad 300. In addition, the test pad 300 may include a comparator (not shown) to compare the output signal TOUT with a reference voltage and to output a result of the comparison as a digital signal.

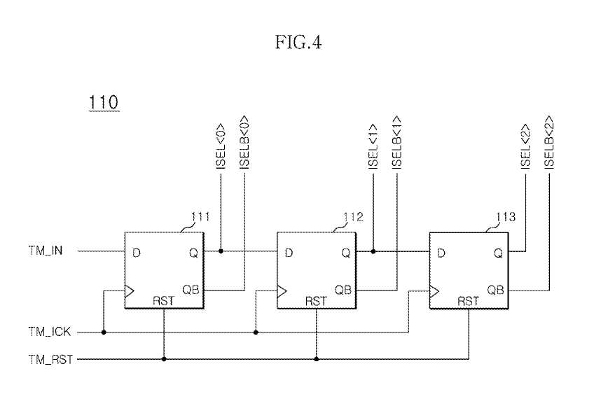

FIG. 4 is a diagram illustrating a configuration capable of being implemented in the upper shifting section 110 shown in FIG. 3. The upper shifting section 110 can be configured as a shift register circuit shown in FIG. 4. The upper shifting section 110 includes first to third flip-flops 111 to 113. The input control signals can include first and second test mode signals TM_IN and TM_ICK. The first flip-flop 111 can receive the first test mode signal TM_IN and the second test mode signal TM_ICK to assist in the generation of the input selection signals ISEL<0:2> and inversion signals ISELB<0:2>. When receiving the first test mode signal TM_IN of a high level, the first flip-flop 111 latches the signal of the high level, and when receiving a pulse signal as the second test mode signal TM_ICK, the first flip-flop 111 outputs the input selection signal ISEL<0> and inversion signal ISELB<0>. The second flip-flop 112 outputs the input selection signal ISEL<1> and inversion signal ISELB<1> when receiving the input selection signal ISEL<0> and receiving a pulse signal as the second test mode signal TM_ICK. Similarly, the third flip-flop 113 outputs the input selection signal ISEL<2> and inversion signal ISELB<2> when receiving the input selection signal ISEL<1> and receiving a pulse signal as the second test mode signal TM_ICK. In addition, the input control signals can include a third test mode signal TM_RST. In order to be reset, the first to third flip-flops 111 to 113 can receive the third test mode signal TM_RST as a reset signal. Therefore, since the upper shifting section 110 has a configuration to enable the input selection signals ISEL<0:2> in sequential order, the upper shifting section 110 can enable a desired input selection signal ISEL<0:2> according to the test mode signals TM_IN, TM_ICK, and TM_RST inputted as the input control signals. The lower shifting section 210 shown in FIG. 3 can be configured in a substantially similar manner as the upper shifting section 110. Only the test mode signals TM_ON, TM_OCK, and TM_RST inputted as the output control signals are differently configured to optionally enable desired output selection signals OSEL<0:2>. In addition, according to embodiments of the present invention, although the shift register circuits are exemplified as an embodiment of the upper shifting section 110 and lower shifting section 210, the present invention is not limited thereto, and can adopt various types of logic circuits to enable a desired selection signal.

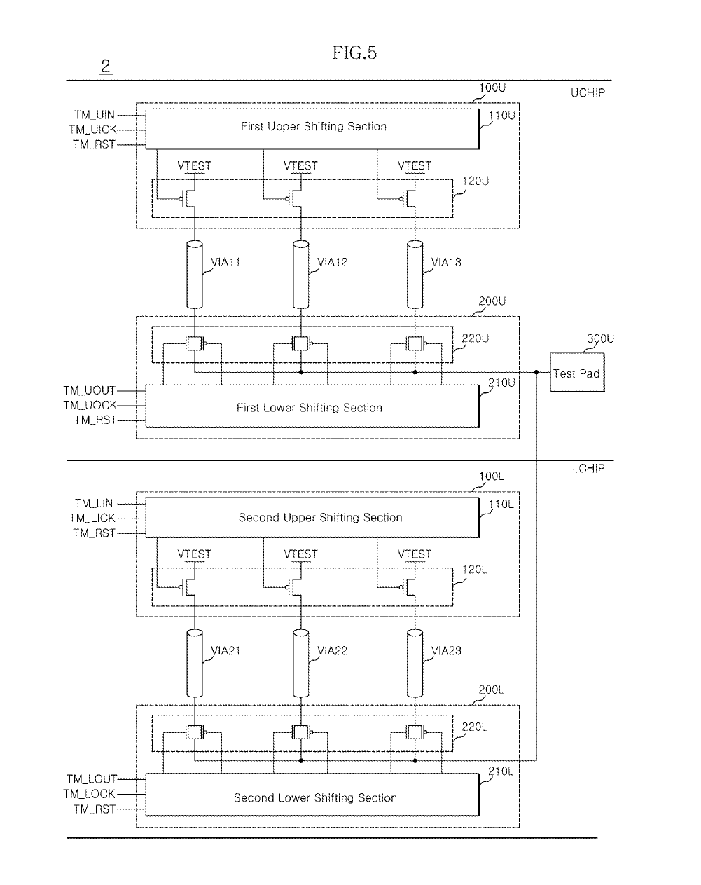

FIG. 5 is a diagram illustrating the configuration of a semiconductor apparatus 2 according to another embodiment of the present invention. In FIG. 5, the semiconductor apparatus 2 includes an upper chip UCHIP and a lower chip LCHIP. The upper chip UCHIP and the lower chip LCHIP are vertically stacked to configure a single semiconductor apparatus 2, and may be electrically connected to each other through a plurality of through-vias. In FIG. 5, the upper chip UCHIP includes first to third through-vias VIA11 to VIA13, and the lower chip LCHIP includes fourth to sixth through-vias VIA21 to VIA23.

When the upper chip UCHIP is stacked on the lower chip LCHIP, the first through-via VIA11 of the upper chip UCHIP is electrically connected to the fourth through-via VIA21 of the lower chip LCHIP, which is located on the same line in the vertical direction. Similarly, the second through-via VIA12 of the upper chip UCHIP is electrically coupled to the fifth through-via VIA 22 of the lower chip LCHIP, and the third through-via VIA13 of the upper chip UCHIP is electrically connected to the sixth through-via VIA 23 of the lower chip LCHIP.

The upper chip UCHIP includes an upper-chip test voltage input unit 100U which applies a test voltage to one or more of the first to third through-vias VIA11 to VIA13. The upper-chip test voltage input unit 100U can be configured as the test voltage input unit 100 shown in FIG. 3. The upper-chip test voltage input unit 100U includes a first upper shifting section 110U and a first test voltage application section 120U. The upper-chip test voltage input unit 100U can apply the test voltage to a desired through-via of the first to third through-vias VIA11 to VIA13.

The lower chip LCHIP includes a lower-chip test result reception unit 200L which receives an output signal TOUT (not shown) outputted from one or more of the fourth to sixth through-vias VIA21 to VIA23. The lower-chip test result reception unit 200L can be configured as the test result reception unit 200 shown in FIG. 3. The lower-chip test result reception unit 200L can include a second lower shifting section 210L and a second output section 220L. The lower-chip test result reception unit 200L can receive an output signal TOUT (not shown) outputted through a desired through-via of the fourth to sixth through-vias VIA21 to VIA23. For example, in an embodiment of the present invention, the lower-chip test result reception unit 200L can receive an output signal TOUT (not shown) outputted from a through-via disposed in the vicinity of a through-via of the lower chip LCHIP which is electrically connected to a through-via, to which the test voltage is applied in the upper chip UCHIP. Thus, when the upper-chip test voltage input unit 100U selects the second through-via VIA12 and applies a test voltage to the second through-via VIA12, the lower-chip test result reception unit 200L can receive an output signal TOUT (not shown) outputted from the fourth and sixth through-vias VIA21 and VIA23 which are adjacent to the fifth through-via VIA 22 that is electrically connected to the second through-via VIA12 when the upper chip UCHIP and the lower chip LCHIP are stacked. In addition, the lower-chip test result reception unit 200L can be coupled to the fourth to sixth through-vias VIA21 to VIA23 in sequential order to receive the output signals TOUTs (not shown), which are outputted through the fourth to sixth through-vias VIA21 to VIA23, in sequential order at a predetermined time interval.

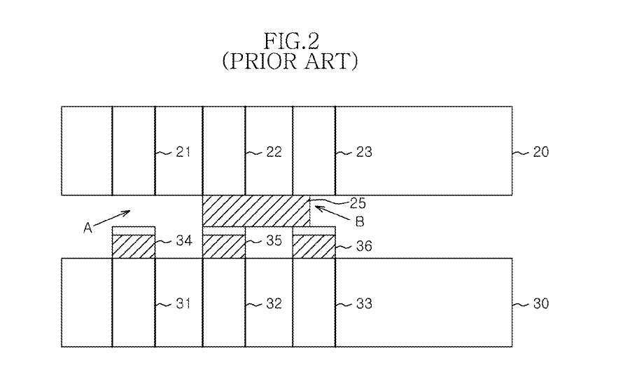

The configuration of the semiconductor apparatus 2 enables a test operation to detect a bump short fail, as indicated by “B” in FIG. 2. It is assumed that, although the second through-via VIA12 is electrically connected to the fifth through-via VIA 22, a short fail with the fourth through-via VIA21 may occur. The upper-chip test voltage input unit 100U can apply a test voltage to the second through-via VIA12, and the lower-chip test result reception unit 200L can receive output signals TOUTs (not shown) outputted through the fourth through-via VIA21 and sixth through-via VIA 23. In this case, since the fourth through-via VIA21 is short-circuited to the second through-via VIA12, the test voltage is applied to the fourth through-via VIA21 through the second through-via VIA12, so that the fourth through-via VIA21 outputs an output signal TOUT (not shown) and thus having a great amount of current. Since the sixth through-via VIA 23 receives no voltage, the sixth through-via VIA 23 does not output current. Therefore, when an output signal TOUT (not shown) having an amount of current is outputted by the fourth through-via VIA21 although the test voltage has not been applied, it can be detected that a through-via of the upper chip UCHIP to which the test voltage is applied is short-circuited to an adjacent through-via of the lower chip LCHIP.

The upper chip UCHIP can additionally include an upper-chip test result reception unit 200U. The upper-chip test result reception unit 200U makes it possible to test whether or not the first to third through-vias VIA11 to VIA13 have been properly formed. In addition, although it is not shown in FIG. 5, when another upper chip is stacked on the upper chip UCHIP, the upper-chip test result reception unit 200U makes it possible to test whether or not the electrical connection between the through-vias of said another upper chip and the upper chip UCHIP have been properly formed. The upper-chip test result reception unit 200U can receive an output signal TOUT (not shown) outputted from one or more of the first to third through-vias VIA11 to VIA13. The upper-chip test result reception unit 200U includes a first lower shifting section 210U and a first output section 220U.

Similarly, the lower chip LCHIP can additionally include a lower-chip test voltage input unit 100L. The lower-chip test voltage input unit 100L makes it possible to test whether or not the fourth to sixth through-vias VIA21 to VIA23 have been properly formed. In addition, although it is not shown in FIG. 5, when another lower chip is stacked on the lower surface of the lower chip LCHIP, the lower-chip test voltage input unit 100L makes it possible to test whether or not the electrical connection between the through-vias of said another lower chip and the lower chip LCHIP have been properly formed. The lower-chip test voltage input unit 100L includes a second upper shifting section 110L and a second test voltage application section 120L.

The upper-chip test voltage input unit 100U, the upper-chip test result reception unit 200U, the lower-chip test voltage input unit 100L, and the lower-chip test result reception unit 200L can receive input control signals TM_UIN, TM_UICK, TM_RST, TM_LIN, and TM_LICK, and output control signals TM_UOUT, TM_UOCK, TM_RST TM_LOUT, and TM_LOCK, configured in mutually different test modes, respectively.

Although FIG. 5 illustrates the case in which two chips are stacked, when two or more chips are stacked, it is possible to perform various types of tests with respect to whether or not through-vias have been properly formed and whether or not the electrical connection of through-vias between the respective chips has been properly formed in various manners by diversely selecting a through-via to which a test voltage is applied and a through-via which outputs an output signal.

In FIG. 5, the test pad 300U can be included in one or both of the upper chip UCHIP and lower chip LCHIP. When the test pad 300U is disposed on the upper chip UCHIP, an output signal TOUT (not shown) provided from the lower-chip test result reception unit 200L can be transmitted through still another through-via to the test pad 300U disposed on the upper chip UCHIP.

While certain embodiments have been described above, it will be understood to those skilled in the art that the embodiments described are by way of example only. Accordingly, the apparatus and method described herein should not be limited based on the described embodiments.

What is claimed is:

1. A semiconductor apparatus which includes a chip comprising a plurality of through-vias, comprising:
a test voltage input unit configured to apply a test voltage to one of the plurality of through-vias; and
a test result reception unit configured to receive an output signal outputted from one or more of the plurality of through-vias.

2. The semiconductor apparatus according to claim 1, wherein a through-via to which the test voltage is applied is different from a through-via which outputs the output signal.

3. The semiconductor apparatus according to claim 1, is wherein a through-via to which the test voltage is applied is disposed in the vicinity of a through-via which outputs the output signal.

4. The semiconductor apparatus according to claim 1, wherein the test voltage input unit comprises:
an upper shifting section configured to generate an input selection signal for selecting one or more of the plurality of through-vias in response to an input control signal; and
a test voltage application section configured to apply the test voltage to the one or more through-vias in response to the input selection signal.

5. The semiconductor apparatus according to claim 1, wherein the test result reception unit comprises:
a lower shifting section configured to generate an output selection signal for selecting one or more of the plurality of through-vias in response to an output control signal; and
an output section configured to provide a test pad with an output signal outputted from one or more of the plurality of through-vias in response to the output selection signal.

6. A semiconductor apparatus comprising:
an upper chip and a lower chip which are stacked in a vertical manner,
wherein the upper chip and the lower chip include a respective plurality of through-vias which are mutually electrically connected;
an upper-chip test voltage input unit configured to apply a test voltage to a specific through-via of the through-vias of the upper chip; and
a lower-chip test result reception unit configured to receive output signals outputted from through-vias which is adjacent to a through-via of the lower chip that is electrically connected to the specific through-via.

7. The semiconductor apparatus according to claim 6, wherein the lower-chip test result reception unit receives output signals outputted from the adjacent through-vias in sequential order.

8. The semiconductor apparatus according to claim 6, wherein upper-chip test voltage input unit comprises:
a first upper shifting section configured to generate an input selection signal for selecting one or more through-vias of the plurality of through-vias of the upper chip in response to an input control signal; and
a first test voltage application section configured to apply the test voltage to the one or more through-vias in response to the input selection signal.

9. The semiconductor apparatus according to claim 6, wherein the lower-chip test result reception unit comprises:
is a first lower shifting section configured to generate an output selection signal for selecting one or more through-vias of the plurality of through-vias of the lower chip in response to an output control signal; and
a first output section configured to provide a test pad with an output signal outputted through the one or more through-vias in response to the output selection signal.

10. The semiconductor apparatus according to claim 9, wherein the first lower shifting section generates the output selection signal to select the adjacent through-vias in sequential order at a predetermined time interval.

11. The semiconductor apparatus according to claim 6, further comprising an upper-chip test result reception unit configured to receive an output signal which is outputted from one of the plurality of through-vias of the upper chip.

12. The semiconductor apparatus according to claim 11, wherein the upper-chip test result reception unit comprises:
a second lower shifting section configured to generate an output selection signal for selecting one or more of the plurality of through-vias in response to an output control signal; and
a second output section configured to provide a test pad with an output signal outputted through the one or more through-vias.

13. The semiconductor apparatus according to claim 6, further comprising a lower-chip test voltage input unit configured to apply the test voltage to one of the plurality of through-vias of the lower chip.

14. The semiconductor apparatus according to claim 13, wherein lower-chip test voltage input unit comprises:
a second upper shifting section configured to generate an input selection signal for selecting one or more through-vias of the plurality of through-vias in response to an input control signal; and
a second test voltage application section configured to apply the test voltage to the one or more through-vias in response to the input selection signal.

15. A test method of a semiconductor apparatus which includes a first through-via of an upper chip, a second through-via of a lower chip which is electrically connected to the first through-via, and a plurality of adjacent through-vias which are disposed in the vicinity of the second through-via in the lower chip, the method comprising the steps of:
outputting a test voltage to the first through-via of the upper chip; and
monitoring an output signal outputted through the plurality of adjacent through-vias of the lower chip.

16. The method according to claim 15, wherein the step of monitoring further comprises providing a test pad with output signals outputted through the plurality of adjacent through-vias in sequential order.

17. The method according to claim 16, further comprising a step of comparing the output signal provided to the test pad with a reference signal and generating a test result.
